(19) United States
(12) Patent Application Publication
(10) Pub. No.: US 2011/0290297 A1
(43) Pub. Date: Dec. 1, 2011

(54) Photovoltaic System, Photovoltaic Module and Method for Assembling a Photovoltaic System

(76) Inventors: Goetz Springer, Dresden (DE); Annemarie Röuspies, Regeusburg (DE); Arthur R. Buechel, Ruggell (LI)

(21) Appl. No.: 13/083,766

(22) Filed: Apr. 11, 2011

Related U.S. Application Data
(63) Continuation of application No. PCT/EP2009/063039, filed on Oct. 7, 2009.

(30) Foreign Application Priority Data
Oct. 10, 2008 (DE) 10 2008 051 249.4

(51) Int. Cl. H01L 31/042; H01L 31/18

(52) U.S. Cl. 136/244; 29/428

(57) ABSTRACT

A photovoltaic system features at least one photovoltaic module, a substructure for accommodating the at least one photovoltaic module, a first supporting element and a second supporting element can be at least partially pushed one into another such that at least two guide elements on a first supporting element engage in the second supporting element. One of the supporting elements is arranged on the rear side of the photovoltaic module and the other supporting element is arranged on the substructure.

This application is a continuation of co-pending International Application No. PCT/EP2009/063039, filed Oct. 7, 2009, which designated the United States and was not published in English, and which claims priority to German Application No. 10 2008 051 249.4, filed Oct. 10, 2008, both of which applications are incorporated herein by reference.

### TECHNICAL FIELD

The invention pertains to a photovoltaic system, a photovoltaic module and a method for assembling a photovoltaic system.

### BACKGROUND

A photovoltaic module (also referred to as a solar module) usually consists of a plurality of electrically interconnected solar cells that convert the radiant energy contained in sunlight into electrical energy by means of the photovoltaic effect.

Photovoltaic modules serve for directly converting solar energy into electric power. For this purpose, thin-layer solar modules have photoactive layers with a thickness on the order of between a few tens of nanometers to a few micrometers. The photoactive layers usually are applied over a large surface of a substrate such as, for example, a glass pane together with contact layers and, if applicable, reflection layers. A plurality of individual strip-shaped solar cells to be electrically connected in series is formed with the aid of several structuring steps. The width of the strip-shaped solar cells that are also referred to as cell strips lies on the order of centimeters. Collectors are usually applied onto the outer cell strips and serve for connecting the thin-layer solar module, as well as for conducting away the generated electric power.

Another flat material, such as, for example, another glass pane, is usually laminated onto the coated substrate in order to protect the photoactive layers from damage and atmospheric influences. A peripheral frame (for example, of aluminum) can be used for reinforcing the solar module, particularly if an unstable or a flexible substrate is used. If no frame is provided, such as, for example, when using glass panes for the substrate and the cover, the module is referred to as a frameless solar module.

An assembly of several photovoltaic modules for generating power is referred to as a photovoltaic system. In this case, the photovoltaic modules are usually provided with a frame that is mounted, for example, screwed, on an elevated support by means of a substructure. In an outdoor system, the photovoltaic module is installed on a substructure mounted on an elevated support. In a rooftop system, the photovoltaic module is usually installed on a substructure that is mounted on a support construction on the roof of the building. However, the photovoltaic module is in certain instances also provided with a substructure that serves as an interface with the roof of the building. Regardless of the type of photovoltaic system, the photovoltaic modules usually are either provided with a frame or supplied in the form of unframed modules.

When mounting a solar module on a substructure, it is usually required to provide the solar module with a mounting system, by means of which the solar module is mounted on a supporting device in another installation step.

To this end, it is possible, for example, to mount frameless thin-layer solar modules on the supporting device by means of the mounting system in the form of a plurality of screw connections.

However, this has the disadvantage that this type of installation is costly and time-consuming, particularly when assembling a photovoltaic system with a large number of photovoltaic modules, such as, for example, in so-called free-standing solar systems.

### SUMMARY OF THE INVENTION

An embodiment of the invention provides a simple option for the installation of photovoltaic modules, in which not only a reliable and cost-efficient, but also a simple and fast installation of photovoltaic modules is ensured.

According to a first embodiment, a photovoltaic system comprises at least one photovoltaic module, a substructure for accommodating the at least one photovoltaic module, and a pair of supporting elements that comprises a first supporting element and a second supporting element. The pair of supporting elements can be pushed, at least partially, one into another so that at least two guide elements on the first supporting element engage in the second supporting element. One of the supporting elements is arranged on the rear side of the photovoltaic module and the other supporting element is arranged, respectively, on the substructure.

According to the invention, the photovoltaic module is provided with a supporting element on the rear side, i.e., the side that lies opposite the main direction of irradiation for converting radiant energy into electrical energy. In this case, the supporting element serves as a mechanical reinforcement for the photovoltaic module, wherein this is particularly advantageous with respect to large frameless modules because potential stress in the module edges can be avoided. Consequently, the photovoltaic modules can be mounted by means of the supporting element only, namely without having to provide the photovoltaic module with a frame or the like. Furthermore, there is no shadowing due to frame elements or module clamps, such that a high efficiency with respect to the conversion of radiant energy into electrical energy can be achieved. The supporting element is inserted into another supporting element that rests on a substructure, wherein the supporting elements are adapted to one another with respect to their shape. Consequently, the photovoltaic module can be installed without requiring any screw connections such that not only a reliable and cost-efficient, but also simple and fast installation of photovoltaic modules is ensured.

In another embodiment, the first supporting element is arranged on a rear side that lies opposite the main irradiation surface in the form of a rear support of the at least one photovoltaic module and the second supporting element is arranged on the substructure in the form of a profiled rod.

Accordingly, the guide elements are arranged on the rear support in the form of projecting elements, protuberances or the like.

In another embodiment, the second supporting element is arranged on a rear side that lies opposite the main irradiation surface in the form of a rear support of the at least one photovoltaic module and the second supporting element is arranged on the substructure in the form of a profiled rod.

Accordingly, the guide elements are arranged on the rear support in the form of projecting elements, protuberances or the like.

In another embodiment, the connecting piece of the rear support is realized with a cross section in the form of a cap profile, a V-profile or a U-profile.

According to this embodiment, the rear support is realized in the form of a torsionally rigid work piece, wherein the at least two adhesive surfaces are arranged on the limbs of the cap profile, V-profile or U-profile. In this case, the adhesive surfaces may be realized continuously, as well as in the form of several segments along the rear support, such that they are essentially arranged parallel to and at a distance from one another. The connecting piece and the adhesive surfaces may be realized in the form of an integral work piece. To this end, it would be possible, for example, to utilize extruded steel or aluminum profiles that allow a simple and cost-efficient manufacture of the rear supports.

In another embodiment, the at least two guide elements are essentially arranged in a minor-inverted fashion relative to one another.

In this embodiment, the alignment of the photovoltaic modules on the substructure and their mounting on the substructure is realized in a single step such that not only a reliable and cost-efficient, but also a simple and fast installation of photovoltaic modules is ensured.

In another embodiment, the first supporting element and the second supporting element are connected to a fixing arrangement.

According to this embodiment, it is possible to realize the alignment of the photovoltaic modules on the substructure and their mounting on the substructure without screw connections. The fixing arrangement may serve as an additional safety measure and is installed after the photovoltaic modules were already pushed onto the profiled rail, wherein this not only ensures a reliable and cost-efficient, but also simple and fast installation of the photovoltaic modules.

According to another aspect, the aforementioned objective is attained with a photovoltaic module that features a rear support arranged on the rear side of the photovoltaic module, wherein the rear support can be pushed into a profiled rod in that either at least two guide elements on the rear support engage in the profiled rod or at least two guide elements on the profiled rod engage in the rear support.

According to the invention, the photovoltaic module is provided with a rear support on its rear side, i.e., the side that lies opposite the main direction of irradiation for converting radiant energy into electrical energy. In this case, the rear support serves as a mechanical reinforcement for the photovoltaic module, wherein this is particularly advantageous with respect to large frameless modules because potential stress on the module edges can be avoided. Consequently, only the rear support is used for mounting the photovoltaic modules and the photovoltaic modules do not have to be provided with a frame or the like.

In another embodiment, the photovoltaic module is realized in the form of a thin-layer photovoltaic module, preferably a rectangular, frameless, thin-layer photovoltaic module.

According to the invention, frameless or framed, thin-layer photovoltaic modules can be easily and cost-efficiently installed in a photovoltaic system. Large-surface photovoltaic modules are particularly desirable for free-standing systems in order to reduce the costs for realizing a substructure. For example, crystalline cells can be laminated into a large-surface module in this fashion.

According to another embodiment, a method for assembling a photovoltaic system comprises supplying at least one photovoltaic module, supplying a substructure for accommodating the at least one photovoltaic module, and supplying a pair of supporting elements that comprises a first supporting element and a second supporting element. The at least two guide elements on the first supporting element engage in the second supporting element. One of the supporting elements is arranged on the rear side of the photovoltaic module and the other supporting element is arranged, respectively, on the substructure. The pair of supporting elements are partially pushed one into another.

Accordingly, a simple installation of the photovoltaic modules is realized by pushing the supporting elements one into another. The modules can be additionally fixed in a separate step. The alignment of the modules is defined due to the mounting of the supporting elements on the substructure. It is possible to completely preassemble the substructure. In this case, it is merely required to insert and, if applicable, additionally fix the photovoltaic modules without having to produce a plurality of screw connections. In this way, it is possible to realize a two-row construction and a three-row construction that can be expanded.

In another embodiment, an assembly jig is used for mounting the profiled rod.

In order to realize the simplest possible installation of the photovoltaic modules, an assembly jig is provided for mounting the profiled rods, wherein this assembly jig defines the alignment of the profiled rail and the distance between the profiled rods in order to achieve a precisely fitted installation of the photovoltaic modules.

Other advantages and characteristics of the invention result from the following description that refers to the figures of the drawings.

### BRIEF DESCRIPTION OF THE DRAWINGS

The invention is described in greater detail below with reference to exemplary embodiments that are illustrated in the drawings. Other advantages, advantageous embodiments and additional developments of the invention result from the exemplary embodiments described below with reference to FIGS. 1 to 5.

In this case, elements, regions and structures that function or act identically are identified by the same reference symbols. If elements, regions or structures correspond with respect to their function, their description is not repeated with reference to each of the exemplary embodiments.

FIG. 1 shows a schematic perspective representation of a photovoltaic system according to an embodiment of the invention;

FIG. 2 shows a schematic cross section through a photovoltaic module and a profiled rod according to an embodiment of the invention;

FIG. 3 shows a schematic cross section through a photovoltaic module and a profiled rod according to an embodiment of the invention;

FIGS. 4A to 4F each show schematic cross sections through a photovoltaic module according to embodiments of the invention; and

FIG. 5 shows a flowchart of a method for assembling photovoltaic modules according to an embodiment of the invention.

### DETAILED DESCRIPTION OF ILLUSTRATIVE EMBODIMENTS

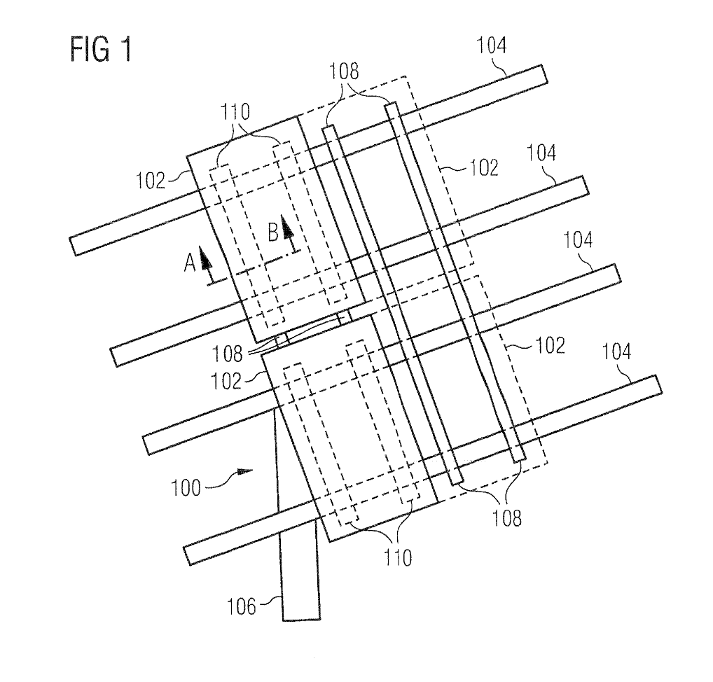

FIG. 1 shows a schematic representation of a photovoltaic system 100 in the form of a perspective side view. The photovoltaic system 100 features several photovoltaic modules 102, wherein the photovoltaic modules 102 are illustrated from their light-sensitive side in FIG. 1. In order to better illustrate elements of a substructure 104 that are arranged on the opposite side of the light-sensitive side, only the contours of two photovoltaic modules 102 are illustrated with broken lines in this figure.

In the exemplary embodiment according to FIG. 1, the photovoltaic modules 102 may be realized, for example, in the form of frameless, thin-film or thin-layer solar modules.

The embodiment of a photovoltaic system 100 is particularly, but not exclusively suitable for photovoltaic modules 102 in the form of frameless, thin-layer solar modules. In this exemplary embodiment, as well as all exemplary embodiments described below, the photovoltaic modules 102 naturally may also be realized in the form of (poly-) crystalline solar modules.

FIG. 1 furthermore shows that the photovoltaic system comprises an elevated support 106 that is connected to the substructure 104. The elevated support 106 is connected, for example, by means of suitable mounting elements in the ground in order to form a free-standing solar system. However, it would also be possible to arrange the substructure on the roof of a building, a flat roof or a façade. In the installation on a façade, the substructure is usually mounted such that it is vertically aligned, wherein an elevated support 106 according to FIG. 1 may be replaced by the façade in this variation if suitable connecting elements are used.

FIG. 1 also shows several profiled rods 108 that are connected to the substructure 104. According to FIG. 1, two horizontal mounting rails are provided as substructure 104 for each row of photovoltaic modules 102. It would naturally also be possible to choose a different arrangement such as, for example, an arrangement that comprises a center purlin that is jointly used by two adjacent rows, as well as an upper and lower purlin for each row of photovoltaic modules 102.

For example, two profiled rods 108 are provided for each photovoltaic module 102, wherein the profiled rods are vertically arranged on the substructure 104 parallel to one another and can accommodate, for example, two photovoltaic modules 102 that lie on top of one another in order to realize a two-row arrangement of photovoltaic modules in the photovoltaic system 100. However, it would also be conceivable to arrange the profiled rails 108 in the horizontal direction. Furthermore, it is also possible to provide a different number of profiled rods 108 for a photovoltaic module 102, e.g., only one profiled rod 108 or more than two profiled rods 108.

The profiled rail 108 serves for accommodating the photovoltaic module 102. A rear support 110 is arranged on the rear side of the photovoltaic module 102 in order to mount the photovoltaic module 102 on the profiled rods 108. The photovoltaic module 102 with the rear support 110 is pushed into the profiled rails 108 as described in greater detail below.

The photovoltaic system 100 illustrated in FIG. 1 merely serves for elucidating the design of the inventive device. It should be clear to a person skilled in the art that a different number of photovoltaic modules 102 can be used in different sizes and arrangements in this case. Consequently, the invention is not limited to two-row arrangements of photovoltaic modules 102, but may also be arbitrarily expanded to three-row or multi-row arrangements. Another option consists of respectively utilizing one or more rear supports 110 for two or more photovoltaic modules, for example, by arranging four photovoltaic modules 102 on two parallel rear supports 110 and pushing the photovoltaic modules into a pair of profiled rods 108.

In this case, the photovoltaic modules 102 may have any size. It would be possible, for example, that the photovoltaic modules 102 have a size of 5 m² or more. The size of the photovoltaic module 102 usually depends on commercially available sizes of flat glass because thin-layer solar modules are manufactured with a glass substrate. A corresponding thin-layer solar module that is manufactured on the basis of commercially available glass has a surface area of approximately 5.7 sqm. It would naturally also be conceivable to use other sizes or blank dimensions such as, for example, the technically common size of approximately 0.6 m×1.2 m.

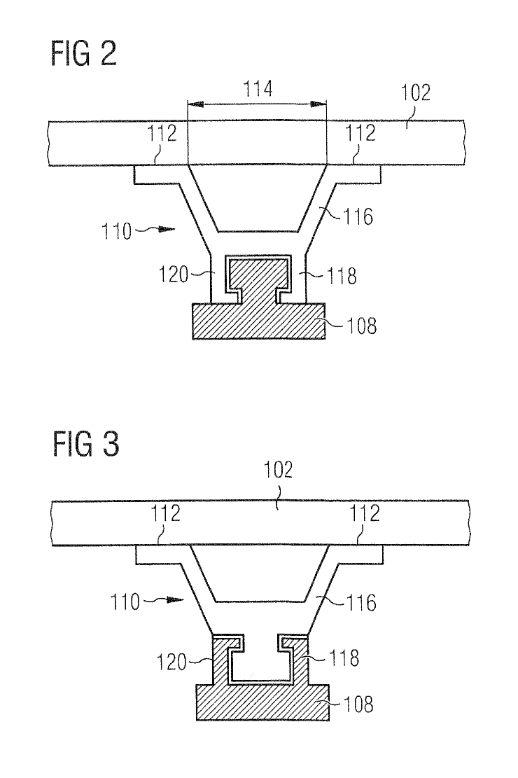

A first embodiment for mounting the photovoltaic module 102 in the profiled rod 108 with the rear support 110 is described in greater detail below with reference to FIG. 2. In this case, FIG. 2 shows a cross section through a photovoltaic module along the line of section A-B illustrated in FIG. 1.

According to FIG. 2, the rear support 110 features two adhesive surfaces 112 that are arranged parallel to and at a distance 114 from one another. However, it would also be conceivable to use a rear support 110 with an adhesive surface 112 that makes it possible, for example, to produce a large-surface connection with the photovoltaic module 102.

An integral work piece that represents the rear support 110 is formed together with a connecting piece 116 that connects the two adhesive surfaces 112 to one another. In this respect, it would be possible to use, for example, extruded steel or aluminum profiles that allow a simple and cost-efficient manufacture of the rear supports 110.

According to FIG. 2, the cross section of the connecting piece 116 of the rear support 110 may be realized in the form of a cap profile. However, it would also be possible to use other profile shapes such as, for example, V-profiles or U-profiles. The rear support 110 serves for mechanically stabilizing the photovoltaic module 102. According to one embodiment, the adhesive surfaces 112 of the rear support 110 are integrally connected to the photovoltaic module 102 by means of an adhesive strip, an adhesive layer or a glue layer. The adhesive connection serves for mechanically fixing the rear support 110 on the photovoltaic module 102. However, the adhesive layer may also serve for realizing electric insulation in order to electrically insulate the photovoltaic module 102 from the rear support 110.

In another embodiment, it is possible to arrange a separating layer of electrically non-conductive material between the rear support 110 and the photovoltaic module 102 in order to achieve the galvanic separation. The rear support 110 may furthermore be realized in such a way that its thermal coefficient of expansion corresponds to that of the photovoltaic module 102 within predetermined limits in order to reduce mechanical stresses caused by temperature changes.

FIG. 2 furthermore shows that the rear support 110 can be pushed onto the profiled rod 108. For this purpose, the rear support 110 features two guide elements 118 and 120 that are adapted to the shape of the profiled rod 108 on the side facing away from the photovoltaic module 102. Extruded steel or aluminum profiles may also be used for the profiled rod 108. In the embodiment illustrated in FIG. 2, the guide elements 118 and 120 are arranged on the connecting piece 116.

In this case, the two guide elements 118 and 120 are arranged on the rear support 110 on opposite ends, respectively, in a minor-inverted fashion. The two guide elements 118 and 120 may be realized in the form of rails with an L-shaped cross section, wherein the facing L-shaped rails partially encompass the profiled rod 108.

However, it would also be conceivable to realize the rails with a hook-shaped or Z-shaped cross section and to arrange the rails such that they face one another in order to partially encompass the profiled rod 108.

Another embodiment for mounting the photovoltaic module 102 in the profiled rod 108 with the rear support 110 is described in greater detail below with reference to FIG. 3. In this case, FIG. 3 shows a cross section through a photovoltaic module along the line of section A-B illustrated in FIG. 1.

As already described above with reference to FIG. 2, the rear support 110 comprises two adhesive surfaces 112 that are arranged parallel to one another. An integral work piece that represents the rear support 110 is formed together with the connecting piece 116 that connects the two adhesive surfaces 112 to one another.

The connecting piece 116 of the rear support 110 is realized with a cross section in the form of a cap profile. However, it would also be possible to use other profile shapes such as, for example, V-profiles or U-profiles. The rear support 110 serves for mechanically stabilizing the photovoltaic module 102.

FIG. 3 furthermore shows that the rear support 110 can be pushed into the profiled rod 108. For this purpose, the profiled rod 108 features two guide elements 118 and 120 that are adapted to the shape of the rear support 110 on the side that faces away from the photovoltaic module 102. The two guide elements 118 and 120 are arranged on the profiled rod 108 on opposite ends, respectively, in a minor-inverted fashion. The two guide elements 118 and 120 may be realized in the form of rails with an L-shaped cross section, wherein the facing L-shaped rails partially encompass the rear support 110.

In summary, a pair of supporting elements is used in each of the embodiments according to FIGS. 2 and 3. The pair of supporting elements comprises a first supporting element and a second supporting element that can be pushed one into another. For this purpose, two guide elements are provided on the first supporting element and at least partially encompass the second supporting element. In this case, one of the supporting elements is arranged on the rear side of the photovoltaic module 102 and the other supporting element is arranged, respectively, on the substructure 104.

In the embodiment according to FIG. 2, the first supporting element is arranged on the rear side in the form of a rear support 110 of the photovoltaic module 102 and the second supporting element is arranged on the substructure 104 in the form of a profiled rod 108.

In the embodiment according to FIG. 3, in contrast, the second supporting element is arranged on the rear side in the form of a rear support 110 of the photovoltaic module 102 and the first supporting element is arranged on the substructure 104 in the form of a profiled rod 108.

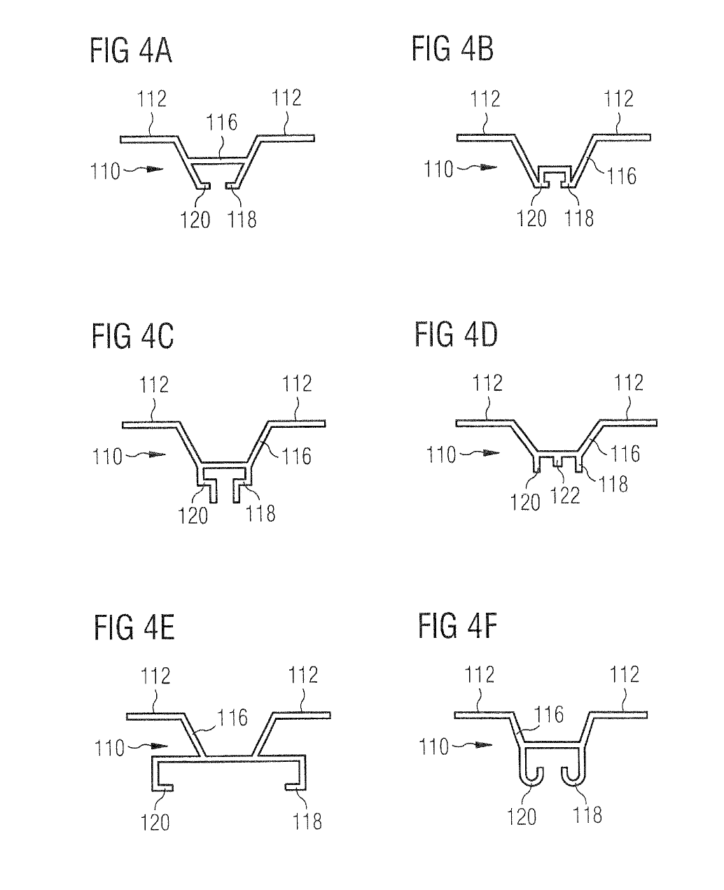

Other exemplary embodiments of the rear support 110 are described below with reference to FIGS. 4A to 4F. The cross-sectional representations once again correspond to the line of section A-B in FIG. 1. These exemplary embodiments are illustrated merely as examples for the mounting concept according to FIG. 2. However, it goes without saying that the exemplary embodiments described below may also be utilized in connection with the profiled rod 108 used, for example, in the mounting concept according to FIG. 3.

In FIG. 4A, the rear support 110 comprises two adhesive surfaces 112 that are arranged parallel to one another. An integral work piece that represents the rear support 110 is formed together with a connecting piece 116 that connects the two adhesive surfaces 112 to one another. According to FIG. 4A, the connecting piece 116 of the rear support 110 is realized with a cross section in the form of a cap profile. The rear support 110 features two guide elements 118 and 120 that are arranged in the form of projecting elements on the side that faces away from the photovoltaic module 102, namely in the line of extension of the sidewalls of the connecting piece 116.

The guide elements 118 and 120 are arranged on the rear support 110 on opposite sides, respectively, in a mirror-inverted fashion. The two guide elements 118 and 120 are realized in the form of rails with an L-shaped cross section such that the facing L-shaped rails can partially encompass the profiled rod 108. In this case, the guide elements 118 and 120 may be realized in the form of continuous rails, as well as in the form of discontinuous rails, along the longitudinal axis of the rear support 110. In the latter instance, the rails would only encompass the profiled rod 108 in individual segments. Naturally, this design may also be chosen for the exemplary embodiments described below.

In FIG. 4B, the rear support 110 once again features two guide elements 118 and 120 that are realized with an L-shaped cross section. In this case, the guide elements 118 and 120 are offset in the direction of the adhesive surfaces 112 such that overall a compact rear support is created.

In the exemplary embodiment illustrated in FIG. 4C, the rear support 110 once again features two guide elements 118 and 120 that are realized with a Z-shaped cross section and arranged in the form of projecting elements on the side that faces away from the photovoltaic module 102.

In FIG. 4D, the rear support 110 features three guide elements 118, 120 and 122 that are essentially arranged parallel to one another and realized in the form of elongated rails. For example, the guide elements 118 and 122, as well as the guide elements 120 and 122, are arranged at the same distance from one another in this case.

In the exemplary embodiment illustrated in FIG. 4E, the rear support 110 once again features two guide elements 118 and 120 that are realized with an L-shaped cross section and arranged in the form of projecting elements on the side that faces away from the photovoltaic module 102 similar to the embodiment according to FIG. 2. However, the two guide elements 118 and 120 are spaced apart from one another by a greater distance than in the embodiment according to FIG. 2. The rear side of the rear support 110 is extended in the horizontal direction for this purpose.

In the exemplary embodiment illustrated in FIG. 4F, the rear support 110 once again features two guide elements 118 and 120 that are realized with a hook-shaped cross section and arranged in the form of projecting elements on the side that faces away from the photovoltaic module 102.

In order to prevent any shifting after the rear support 110 and the profiled rod 108 are pushed one into another, a fixing arrangement may be provided that connects the rear support 110 to the profiled rod 108. For example, the fixing arrangement may be realized in the form of a screw connection produced with one or more hammer-head bolts. However, it would also be conceivable to realize the fixing arrangement with the aid of rivets or clamps.

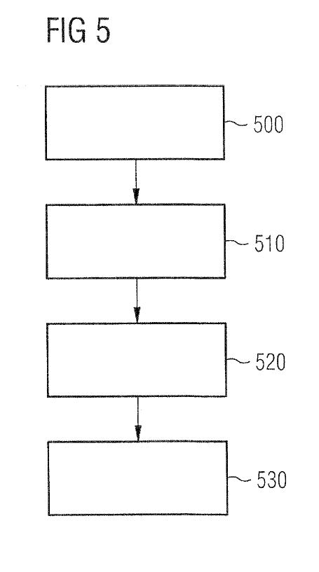

Process steps for assembling a photovoltaic system are described below with reference to the flowchart illustrated in FIG. 5.

At least one photovoltaic module is supplied in step 500.

A substructure 104 for accommodating the at least one photovoltaic module 102 is supplied in step 510.

In step 520, a pair of supporting elements is supplied that comprises a first supporting element and a second supporting element, wherein at least two guide elements on the first supporting elements at least partially encompass the second supporting element, and wherein one of the supporting elements is arranged on the rear side of the photovoltaic module and the other supporting element is arranged, respectively, on the substructure.

In step 530, the pair of supporting elements is at least partially pushed one into another.

In summary, the invention makes available a simple and cost-efficient mounting option for large-surface photovoltaic modules that may form, for example, a free-standing solar system.

The description of the exemplary embodiments does not restrict the invention in any way. On the contrary, the invention includes any new characteristic, as well as any combination of characteristics, particularly any combination of characteristics in the claims, namely even if this characteristic or this combination is not individually and explicitly defined in the claims or the exemplary embodiments.

1-20. (canceled)

21. A photovoltaic system, comprising:
at least one photovoltaic module;
a substructure for accommodating the at least one photovoltaic module; and
a first supporting element and a second supporting element that can be at least partially pushed one into another such that at least two guide elements on the first supporting element engage in the second supporting element, wherein one of the first or second supporting elements is arranged on a rear side of the photovoltaic module and the other of the first or second supporting elements is arranged on the substructure.

22. The photovoltaic system according to claim 21, wherein the one of the first or second supporting elements that is arranged on the rear side of the at least one photovoltaic module is in the form of a rear support and wherein other one of first or second supporting elements that is arranged on the substructure is in the form of a profiled rod, wherein the rear side lies opposite a main irradiation surface of the photovoltaic module.

23. The photovoltaic system according to claim 22, wherein the first supporting element comprises the rear support and wherein the second supporting element comprises the profiled rod.

24. The photovoltaic system according to claim 22, wherein the second supporting element comprises the rear support and the first supporting element comprises the profiled rod.

25. The photovoltaic system according to claim 22, wherein the rear support comprises an adhesive surface and a connecting piece, wherein the at least two guide elements are arranged on the connecting piece in order to at least partially encompass the profiled rod.

26. The photovoltaic system according to claim 25, wherein the adhesive surface of the rear support is connected to the at least one photovoltaic module by an adhesive strip or by an adhesive layer.

27. The photovoltaic system according to claim 25, wherein the connecting piece is realized with a cross section in the form of a cap profile, a V-profile or a U-profile.

28. The photovoltaic system according to claim 22, wherein the first supporting element and the second supporting element are connected to a fixing arrangement.

29. The photovoltaic system according to claim 28, wherein the fixing arrangement comprises a screw connection that is produced by one or more hammer-head bolts.

30. The photovoltaic system according to claim 28, wherein the fixing arrangement is comprises rivets or clamps.

31. The photovoltaic system according to claim 21, wherein the at least two guide elements each comprise a rail with a hook-shaped cross section, the at least two guide elements arranged such that they face one another.

32. The photovoltaic system according to claim 21, wherein the at least two guide elements each comprise a rail with an L-shaped or Z-shaped cross section, the at least two guide elements arranged such that they face one another.

33. The photovoltaic system according to claim 22, wherein the profiled rod is vertically mounted on the substructure.

34. The photovoltaic system according to claim 22, wherein the profiled rod is horizontally mounted on the substructure.

35. The photovoltaic system according to claim 22, wherein the profiled rod and the rear support are adapted to one another with respect to their mechanical stability and their fitting accuracy.

36. A photovoltaic module comprising:
a rear support that is arranged on a rear side of a photovoltaic module, wherein the rear support can be pushed into a profiled rod such that either at least two guide elements on the rear support at least partially encompass a profiled rod or at least two guide elements on the profiled rod engage in the rear support.

37. The photovoltaic module according to claim 36, wherein the rear support comprises an adhesive surface and a connecting piece, wherein the at least two guide elements are arranged on the connecting piece in order to at least partially encompass the rear support.

38. The photovoltaic module according to claim 36, wherein the at least two guide elements each comprise a rail with a hook-shaped cross section and wherein the at least two guide elements are arranged such that they face one another.

39. The photovoltaic module according to claim 36, wherein the at least two guide elements each comprise a rail with an L-shaped or Z-shaped cross section and wherein the at least two guide elements are arranged such that they face one another.

40. The photovoltaic module according to claim 36, wherein the photovoltaic module comprises a rectangular, frameless, thin-layer photovoltaic module.

41. A method for assembling a photovoltaic system, the method comprising:
providing at least one photovoltaic module;
providing a substructure for accommodating the at least one photovoltaic module;
providing a pair of supporting elements that comprises a first supporting element and a second supporting element, wherein at least two guide elements on the first supporting element at least partially encompass the second supporting element, and wherein one of the supporting elements is arranged on a rear side of the photovoltaic module and the other supporting element is arranged on the substructure; and
at least partially pushing the pair of supporting elements one into another.
